(19) United States
(12) Patent Application Publication
(10) Pub. No.: US 2025/0193522 A1
(43) Pub. Date: Jun. 12, 2025

(54) METHOD FOR ESTABLISHING ELECTRICAL CONNECTION, CAMERA MODULE AND ELECTRONIC DEVICE HAVING THE CAMERA MODULE

(71) Applicant: TRIPLE WIN TECHNOLOGY (SHENZHEN) CO LTD., Shenzhen (CN)

(72) Inventor: FEI-FAN YU, Shenzhen (CN)

(21) Appl. No.: 18/648,245

(22) Filed: Apr. 26, 2024

(30) Foreign Application Priority Data
Dec. 7, 2023 (CN) 202311690956.4

(51) Int. Cl. H04N 23/68; G03B 13/34; H04N 23/54

(52) U.S. Cl. CPC H04N 23/687; G03B 13/34; H04N 23/54

(57) ABSTRACT

A method for electrical connection is presented, including preparing a pre-bonding assembly with a first and second connection pad and an insulating layer, where the first pad includes two sections, with the second staggered and covered by the insulating layer. An activatable conductive film, filled with isolated conductive particles, is placed between the first pad's section and the second pad. Upon pressing, the film activates, extending into the insulating layer, connecting the first section and second pad electrically, while isolating the second section. This provides a reliable connection, suitable for camera modules and other electronics.

### FIELD

The subject matter herein generally relates to electrical connection in electronic devices, and more particularly, to a method for establishing electrical connection, a camera module assembled using the method, and an electronic device having the camera module.

### BACKGROUND

Anisotropic conductive films (ACFs) are generally composed of polymer-based matrix with conductive fillers such as metallic particles or metal-coated polymer spheres. The ACFs can provide unidirectional electrical conductivity in the vertical direction. A camera module may use the ACF to connect pads of a flexible board to a lens.

However, when heat and pressure are applied to the ACFs, the conductive fillers may become unevenly distributed in the ACFs, leading to potential signal interference among the pads. The signal interference can degrade the performance of electronic circuits and, in worse cases, affect the overall reliability and functionality of camera module.

### BRIEF DESCRIPTION OF THE DRAWINGS

Implementations of the present technology will now be described, by way of example only, with reference to the attached figures.

FIG. 1 is a flowchart of a method for establishing electrical connection according to an embodiment of the present application.

FIG. 2 is a cross-sectional view of a pre-bonding assembly according to an embodiment of the present application.

FIG. 3 is a top view of a circuit board assembly of the pre-bonding assembly in FIG. 2.

FIG. 4 is a cross-sectional view showing an activatable conductive film being formed on the pre-bonding assembly in FIG. 2.

FIG. 5 is a cross-sectional view showing the pre-bonding assembly and the activatable conductive film in FIG. 4 being pressed.

FIG. 6 is a cross-sectional view of a camera module formed after pressing the pre-bonding assembly and the activatable conductive film in FIG. 5.

FIG. 7 is a diagrammatic view of an electronic device provided by an embodiment of the present application.

### DETAILED DESCRIPTION

It will be appreciated that for simplicity and clarity of illustration, where appropriate, reference numerals have been repeated among the different figures to indicate corresponding or analogous members. In addition, numerous specific details are set forth in order to provide a thorough understanding of the embodiments described herein. However, it will be understood by those of ordinary skill in the art that the embodiments described herein can be practiced without these specific details. In other instances, methods, procedures, and members have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to;” it specifically indicates open-ended inclusion or membership in the so-described combination, group, series, and the like.

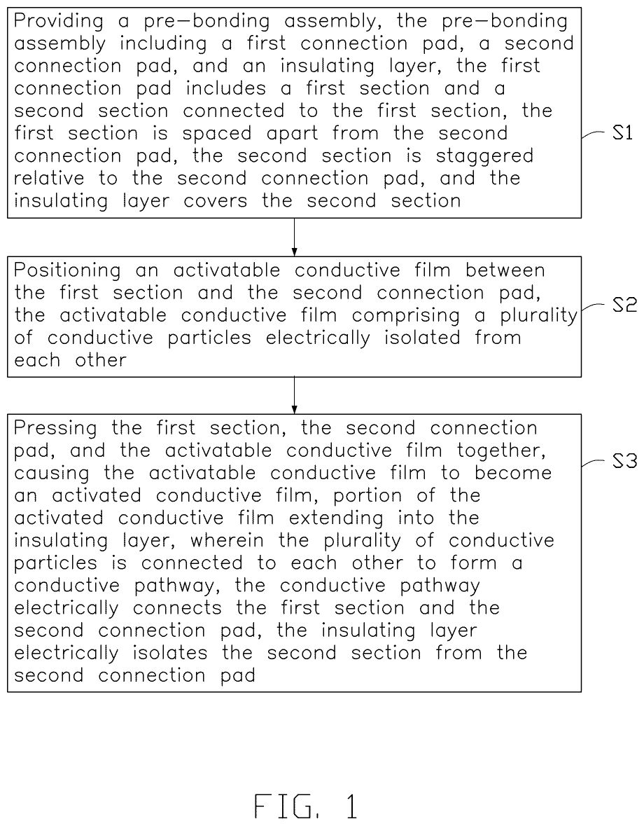

Referring to FIG. 1, an embodiment of the present application provides a method for establishing electrical connection in camera assembly. In other embodiments, the method could be applied in various scenarios requiring electrical connections, such as among LEDs and control circuits in displays, automotive dashboards, medical devices, and other display systems. The method is provided by way of example, as there are a variety of ways to carry out the method. Each block shown in FIG. 1 represents one or more processes, methods, or subroutines, carried out in the example method. Furthermore, the illustrated order of blocks is illustrative only and the order of the blocks can change. Additional blocks can be added, or fewer blocks may be utilized or the order of the blocks may be changed, without departing from this disclosure. The method can begin at block S1.

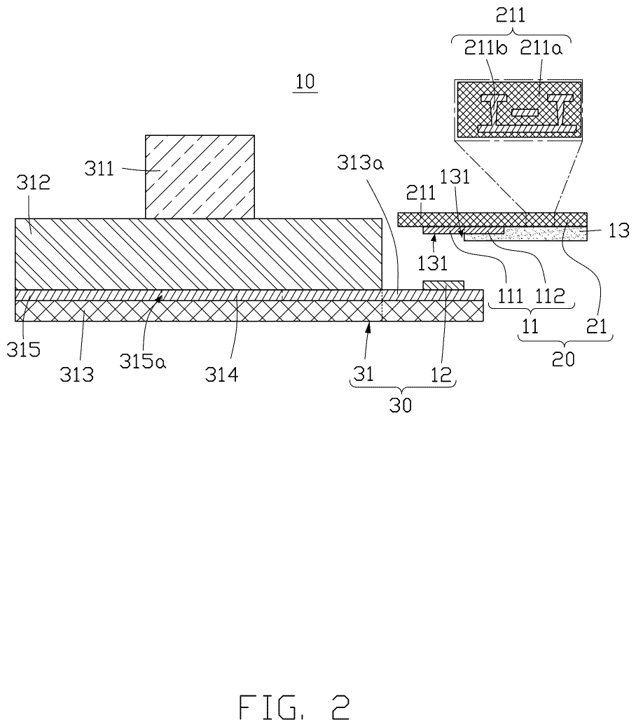

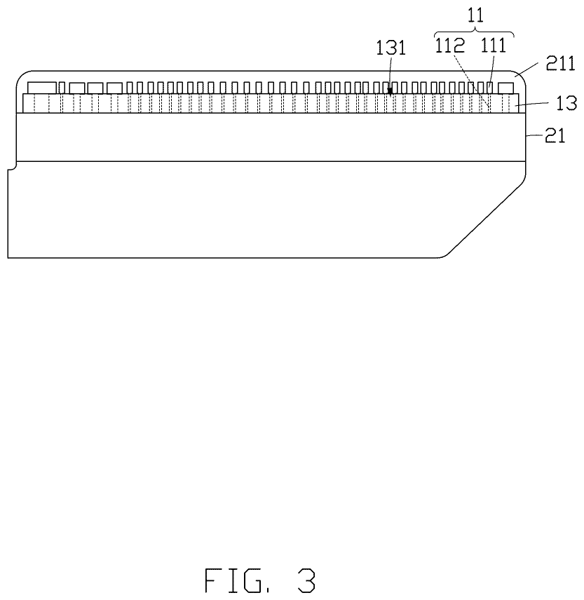

Block S1, referring to FIGS. 2 and 3, a pre-bonding assembly 10 is provided. The pre-bonding assembly 10 includes a first connection pad 11, a second connection pad 12, and an insulating layer 13. The first connection pad 11 includes a first section 111 corresponding to the second connection pad 12 and a second section 112 connected to the first section 111. The first section 111 is spaced apart from the second connection pad 12. The second section 112 is staggered relative to the second connection pad 12. The insulating layer 13 covers the second section 111. The insulating layer 13 includes materials such as aluminum oxide (Al₂O₃), silicon dioxide (SiO₂) for oxide layers, and polyimide, polytetrafluoroethylene (PTFE), or polyethylene (PE).

In this embodiment, the pre-bonding assembly 10 further includes a circuit board assembly 20 and a lens assembly 30. The circuit board assembly 20 includes a first body 21 with the first connection pad 11. The first connection pad 11 is arranged on an outer surface of the first body 21. The lens assembly 30 includes a second body 31 with the second connection pad 12. The second connection pad 12 is arranged on an outer surface of the second body 31. The first section 111 is configured to face the second connection pad 12.

In this embodiment, the first body 21 includes a flexible board 211, which includes a base layer 211a and a conductive structure 211b embedded within the base layer 211a. The first connection pad 11 is formed on one side of the base layer 211a facing the second body 31. The first connection pad 11 is connected to the conductive structure 211b. The insulating layer 13 is formed on the base layer 211a. The insulating layer 12 covers the second section 112 and electrically isolate the second sections 112 from ambient condition. The insulating layer 13 defines an opening 131. The first section 111 of the first connection pad 11 is exposed from the opening 131. The base layer 211a is made of polyimide. In other embodiments, the first body 21 may be a rigid board or a combination of rigid and flexible boards.

In this embodiment, the second body 31 includes a lens component 311, a voice coil motor 312, an image stabilization unit 313, an image sensor 314, and a bracket 315. The lens component 311 is connected to one side of the voice coil motor 312. The bracket 315 is connected to the other side of the voice coil motor 312. The image stabilization unit 313 is connected to the bracket 315. The bracket 315 defines a through hole 315a, and the image sensor 314 is disposed on the through hole 315a.

The lens component 311 can converge and guide light to the image sensor 314. The voice coil motor 312 can control the movement of the lens component 311 for rapid and precise focusing. The image stabilization unit 313 can adjusts the position of the image sensor 314 to counteract minor movements or vibrations, thereby enhancing image quality.

The image stabilization unit 313 and the bracket 315 extend beyond an edge of the voice coil motor 312 to form a connection portion 313a. The connection portion 313a is electrically connected to the voice coil motor 312. The second connection pad 12 are arranged on a surface of the connection portion 313a facing the first body 21, allowing for electrical connection between the second connection pad 12 and the first connection pad 11, thereby establishing electrical connection between the second body 31 and the first body 21.

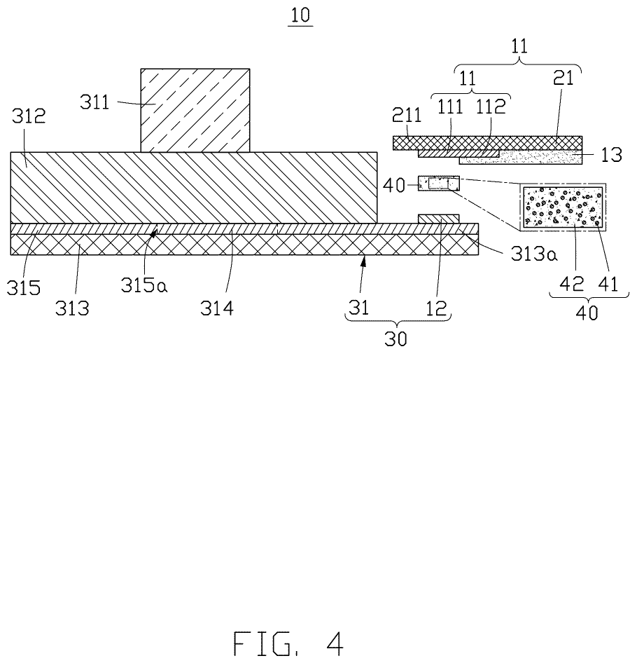

Block S2, referring to FIG. 4, an activatable conductive film 40 is disposed between the first connection pad 11 and the second connection pad 12. The activatable conductive film 40 includes a plurality of conductive particles 41 and an adhesive 42. The conductive particles 41 are dispersed within the adhesive 42. The conductive particles 41 are electrically isolated from each other, so that the activable conductive film 40 is electrically insulated as a whole. The conductive particles 41 is made from materials like gold (Au), nickel (Ni), nickel/gold (Ni/Au), silver (Ag), or copper (Cu). The adhesive 42 is a thermosetting resin such as epoxy resin, polyimides, or phenolic resin.

Block S3, referring to FIGS. 4, 5, and 6, the first connection pad 11, the second connection pad 12, and the activatable conductive film 40 are pressed together to obtain a camera module 100. The pressing action transforms the activatable conductive film 40 into an activated conductive film 43. The activated conductive film 43 is connected between the first section 111 and the second pad 12. A portion of the activated conductive film 40 extends onto the insulating layer 13. The conductive particles 41 are interconnected to each other to form a conductive pathway 411. The conductive pathway 411 establishes an electrical connection between the first section 111 and the second pad 12. The insulating layer 13 electrically isolates the conductive pathway 411 from the second section 112, thereby insulating the second section 112 and the second conductive pad 12.

In this embodiment, heat is applied to the adhesive 42 of the activatable conductive film 40, causing the adhesive 42 to be cured to form a bonding matrix 44. The bonding matrix 44 defines a thickness A1 direction. The conductive particles 41 are in contact with each other along the thickness direction A1 to form the conductive pathway 411 inside the bonding matrix 44, thereby establishing electrical connection between the first section 111 and the second connection pad 12.

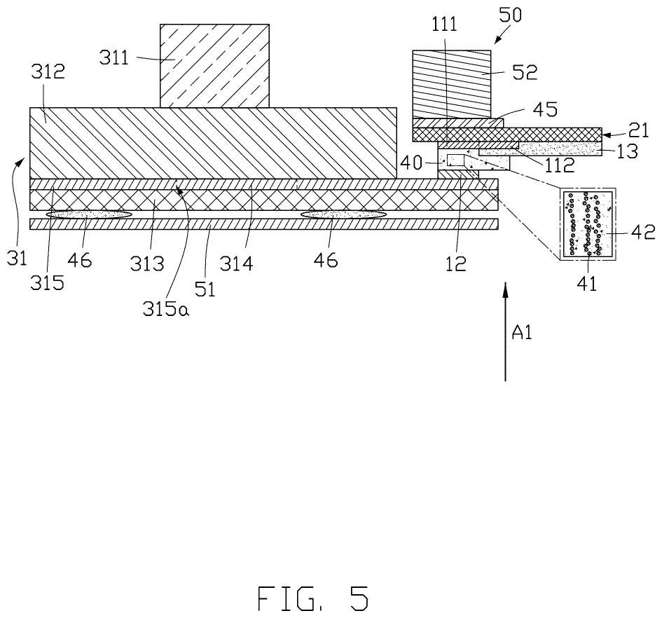

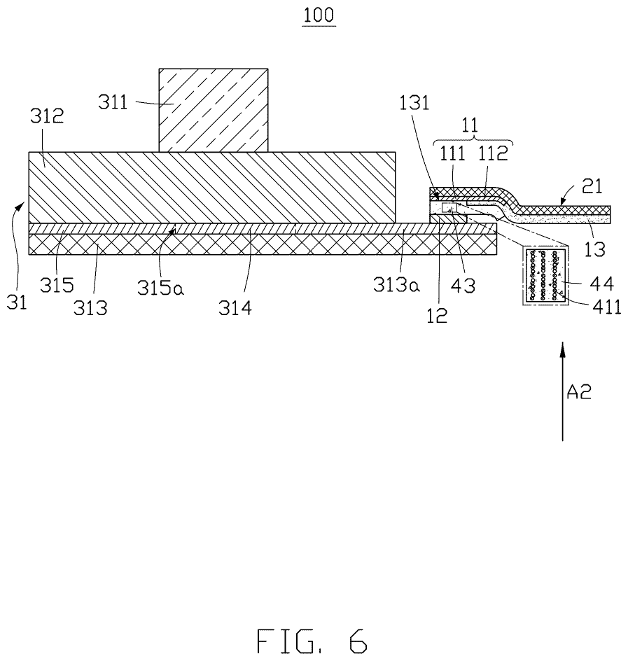

In this embodiment, referring to FIGS. 5 and 6, the block S3 further includes:

Block S31, referring to FIG. 5, a heat press machine 50 is provided, and the heat press machine 50 includes a base 51 and a heating head 52. The base 51 is used for supporting the lens assembly 30. The heating head 52 is used for applying pressure and heat to the circuit board assembly 20.

Block S32, referring to FIGS. 5 and 6, the pre-bonding assembly 10 and the activatable conductive film 40 are both placed between the base 51 and the heating head 52. The second body 31 is supported by the base 51. The first body 21 faces the heating head 52. The activatable conductive film 40 is disposed between the first connection pad 11 and the second connection pad 12.

Block S33, referring to FIG. 6, the heating head 52 moves towards the base 51 and applies a pressure force onto the first body 21. The base 51 applies another pressure force onto the second body 31. Both pressure forces transform the activatable conductive film 40 into the activated conductive film 43. Meanwhile, heat transferred from the heating head 52 to the activatable conductive film 40 and cures the adhesive 42 into the bonding matrix 44.

In this embodiment, referring to FIGS. 5 and 6, the block S3 further includes:

Block S34, referring to FIG. 6, a first cushioning pad 45 is disposed between the heating head 52 and the second body 31, and a second cushioning pad 46 is disposed between the base 51 and the first body 21. The first cushioning pad 45 and the second cushioning pad 46 can stabilize the pre-bonding assembly 10, and evenly distribute the pressure and heat to the activatable conductive film 40. In this embodiment, the first cushioning pad 45 is made of silicone, and the second cushioning pad 46 is made of rubber or polyurethane.

The method provided by this application employs the insulating layer 13 on the second section 112 of the first connection pad 11, and then pressing the first connection pad 11, the second connection pad 12, and the activatable conductive film 40. The method can minimize the risk of short circuits between the second section 112 and the second connection pad 12 during the pressing process. The insulating layer 13 not only isolates the second section 112 from the second connection pad 12, but also reduces the susceptibility of the camera module 100 to external electrostatic influences and signal interference, thereby enhancing the overall reliability of the camera module 100.

Referring to FIG. 6, a camera module 100 is provided according to an embodiment of the application. The camera module 100 includes a circuit board assembly 20, a lens assembly 30, and an activated conductive film 43. The circuit board assembly 20 includes a first connection pad 11, and the first connection pad 11 includes a first section 111 and the second section 112. The second section 112 is covered by an insulating layer 13. The lens assembly 30 comprises a second connection pad 12, which corresponds to the first section 111 and staggered from the second section 112. The activated conductive film 43 is connected between the first section 112 and the second connection pad 12. The activated conductive film 43 includes a bonding matrix 44 and a conductive pathway 411 within the boding matrix 44. The conductive pathway 411 is electrically connected between the first section 111 and the second connection pad 12. The insulating layer 13 electrically isolates the second section 112 from the second connection pad 12.

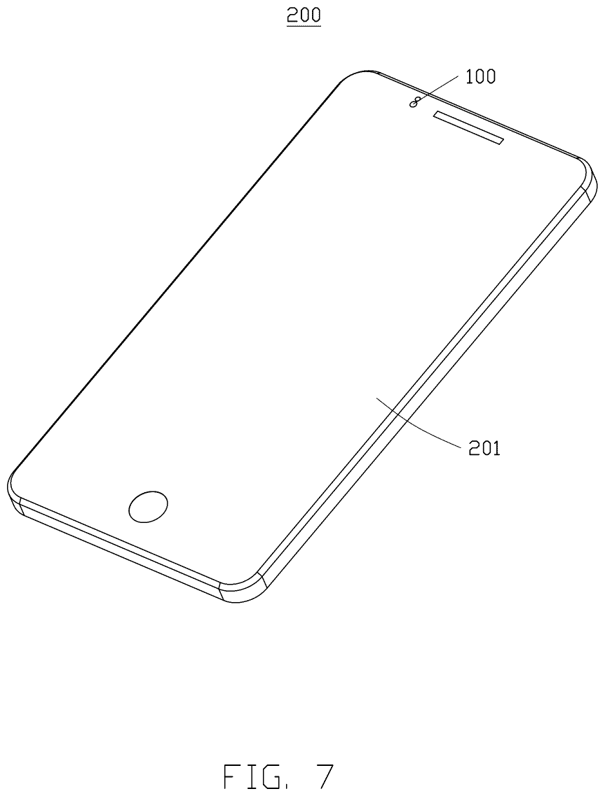

Referring to FIG. 7, an electronic device 200 is provided according to an embodiment of this application. The electronic device 200 includes the camera module 100 and a casing 201. The camera module 100 is partially exposed on the casing 201. The electronic device 200 may be a smartphone, tablet, or smartwatch with camera functionality.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A method for establishing electrical connection, comprising:
providing a pre-bonding assembly, wherein the pre-bonding assembly comprises a first connection pad, a second connection pad, and an insulating layer, the first connection pad comprises a first section and a second section connected to the first section, the first section is spaced apart from the second connection pad, the second section is staggered relative to the second connection pad, and the insulating layer covers the second section;
placing an activatable conductive film between the first section and the second connection pad, the activatable conductive film comprising a plurality of conductive particles electrically isolated from each other;
pressing the first section, the second connection pad, and the activatable conductive film together, causing the activatable conductive film to become an activated conductive film, a portion of the activated conductive film extending into the insulating layer, wherein the plurality of conductive particles in the activated conductive film is connected to each other to form a conductive pathway, the conductive pathway electrically connects the first section to the second connection pad, and the insulating layer electrically isolates the second section from the second connection pad.

2. The method of claim 1, wherein the pre-bonding assembly further comprises a lens assembly and a circuit board assembly, the lens assembly comprises a first body, the first connection pad is arranged on the first body, the circuit board assembly comprises a second body, and the second connection pad is arranged on the second body.

3. The method of claim 1, wherein the activatable conductive film further comprises an adhesive, the plurality of conductive particles is dispersed within the adhesive, the method further comprises:
heating and curing the adhesive to form a bonding matrix, wherein the bonding matrix defines a thickness direction, the conductive pathway is electrically connected to the first section and the second connection pad along the thickness direction.

4. The method of claim 3, wherein the plurality of conductive particles is made from gold, nickel, silver, or copper, and the adhesive is made from epoxy resins, polyimides, or phenolic resins.

5. The method of claim 2, wherein of the pressing comprises:
providing a heat press machine, wherein the heat press machine comprises a base and a heating head;
placing the pre-bonding assembly and the activatable conductive film between the base and the heating head, wherein the base supports the first body, the second body faces the heating head, the activatable conductive film is placed between the first section and the second connection pad;
moving the heating head towards the base, causing the heating head to apply pressure onto the second body and the base to apply pressure onto the first body, thereby causing the activatable conductive film to become the activated conductive film.

6. The method of claim 5, further comprising:
placing a first cushioning pad between the heating head and the second body; and
placing a second cushioning pad between the base and the first body.

7. The method of claim 6, wherein the first cushioning pad is made of silicone, and the second cushioning pad is made of rubber or polyurethane.

8. A camera module, comprising:
a circuit board assembly comprising a first connection pad and an insulating layer, the first connection pad comprising a first section and a second section, the insulating layer covering the first section;
a lens assembly comprising a second connection pad, wherein the second connection pad corresponds to the first section, the second section is staggered from the second connection pad;
an activated conductive film positioned between the first connection pad and the second connection pad, the activated conductive film comprising a conductive pathway, wherein the conductive pathway electrically connects the first section and the second connection pad, and the insulating layer electrically isolates the second section from the second connection pad.

9. The camera module of claim 8, wherein the circuit board assembly further comprises a base layer and a conductive structure in the base layer, the first connection pad is arranged on the base layer, the first connection pad is connected to the conductive structure, the insulating layer is connected to the base layer, the insulating layer covers the first connection pad, the insulating layer defines an opening, and the first section is exposed from the opening.

10. The camera module of claim 8, wherein the lens assembly further comprises a lens component, a voice coil motor, an image stabilization unit, and an image sensor, the lens component is connected to one side of the voice coil motor, the image stabilization unit is connected to another side of the voice coil motor, and the image sensor is disposed on the image stabilization unit.

11. The camera module of claim 10, wherein the image stabilization unit protrudes from an edge of the voice coil motor to form a connection portion, the connection portion is electrically connected to the voice coil motor, and the second connection pad is arranged on the connection portion.

12. The camera module of claim 8, wherein the activated conductive film further comprises a bonding matrix, the boding matrix defines a thickness direction, and the conductive pathway is disposed in the bonding matrix in the thickness direction.

13. The camera module of claim 12, wherein the conductive pathway is made from gold, nickel, silver, or copper, and the boding matrix is made from epoxy resins, polyimides, or phenolic resins.

14. An electronic device, comprising:
a casing; and
a camera module partially exposed from the casing, wherein the camera module comprises:
a circuit board assembly comprises a first connection pad and an insulating layer, the first connection pad comprising a first section and a second section, the insulating layer covering the first section;
a lens assembly comprises a second connection pad, the second connection pad corresponds to the first section, the second section is staggered from the second connection pad;
an activated conductive film positioned between the first connection pad and the second connection pad, the activated conductive film comprise a conductive pathway, wherein the conductive pathway electrically connects the first section and the second connection pad, and the insulating layer electrically isolates the second section from the second connection pad.

15. The electronic device of claim 14, wherein the circuit board assembly further comprises a base layer and a conductive structure in the base layer, the first connection pad is arranged on the base layer, the first connection pad is connected to the conductive structure, the insulating layer is connected to the base layer, the insulating layer covers the first connection pad, the insulating layer defines an opening, and the first section is exposed from the opening.

16. The electronic device of claim 14, wherein the lens assembly further comprises a lens component, a voice coil motor, an image stabilization unit, and an image sensor, the lens component is connected to one side of the voice coil motor, the image stabilization unit is connected to another side of the voice coil motor, and the image sensor is disposed on the image stabilization unit.

17. The electronic device of claim 16, wherein the image stabilization unit protrudes from an edge of the voice coil motor to form a connection portion, the connection portion is electrically connected to the voice coil motor, and the second connection pad is arranged on the connection portion.

18. The electronic device of claim 14, wherein the activated conductive film further comprises a bonding matrix, the boding matrix defines a thickness direction, and the conductive pathway is disposed in the bonding matrix in the thickness direction.

19. The electronic device of claim 18, wherein the conductive pathway is made from gold, nickel, silver, or copper, the boding matrix is made from epoxy resins, polyimides, or phenolic resins.

20. The electronic device of claim 14, wherein the electronic device is selected from a smartphone, tablet, or smartwatch with camera functionality.
